(19) United States
(12) Patent Application Publication
(10) Pub. No.: US 2026/0271803 A1
(43) Pub. Date: Sep. 10, 2026

(54) ELECTRONIC DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Tomohiro SAITO, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/542,738

(22) Filed: Feb. 18, 2026

(30) Foreign Application Priority Data
Mar. 5, 2025 (JP) 2025-034773

(51) Int. Cl. H10W 90/00; H10W 20/46; H10W 72/29; H10W 90/26

(52) U.S. Cl. CPC H10W 90/722; H10W 20/46; H10W 72/29; H10W 90/26

(57) ABSTRACT

An electronic device includes a substrate, an insulating layer provided on the substrate and including a surface located on a side opposite to the substrate, a through hole extending through the insulating layer and the substrate in a first direction, and a conductive film provided on the surface of the insulating layer and on an inner side surface of the insulating layer in the through hole. The insulating layer includes a recessed portion recessed toward the substrate from the surface and exposed from the conductive film.

### CROSS-REFERENCE TO RELATED APPLICATION

This application is based upon and claims the benefit of priority from Japanese Patent Application No. 2025-034773, filed on Mar. 5, 2025; the entire contents of which are incorporated herein by reference.

### FIELD

Embodiments of the invention relate to an electronic device.

### BACKGROUND

For example, in an electron-beam control device including a through hole through which an electron beam passes, if an insulating layer exposed in the vicinity of the through hole is charged, an unintended electric field is generated in the vicinity of the through hole, which can affect the path of the electron beam passing through the through hole. When a conductive antistatic film is formed on the surface of the insulating layer, the effect of the charging of the insulating layer can be reduced. However, if there is a portion of the surface of the insulating layer exposed from the antistatic film, the exposed portion has an effect if charged.

### BRIEF DESCRIPTION OF THE DRAWINGS

FIG. 1 is a schematic plan view of an electronic device according to a first embodiment;

FIG. 2 is a cross-sectional view taken along line A-A in FIG. 1;

FIGS. 3A to 3C are schematic cross-sectional views showing modifications of the electronic device according to the embodiment;

FIG. 4 is a schematic plan view showing a modification of the electronic device according to the embodiment;

FIGS. 5A and 5B are schematic cross-sectional views showing modifications of the electronic device according to the embodiment;

FIG. 6 is a schematic plan view of an electronic device according to a second embodiment; and

FIG. 7 is a cross-sectional view taken along line B-B in FIG. 6.

### DETAILED DESCRIPTION

According to embodiments of the invention, an electronic device includes a substrate, an insulating layer provided on the substrate and including a surface located on a side opposite to the substrate, a through hole extending through the insulating layer and the substrate in a first direction, and a conductive film provided on the surface of the insulating layer and on an inner side surface of the insulating layer in the through hole, the insulating layer including a recessed portion recessed toward the substrate from the surface and exposed from the conductive film.

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

### First Embodiment

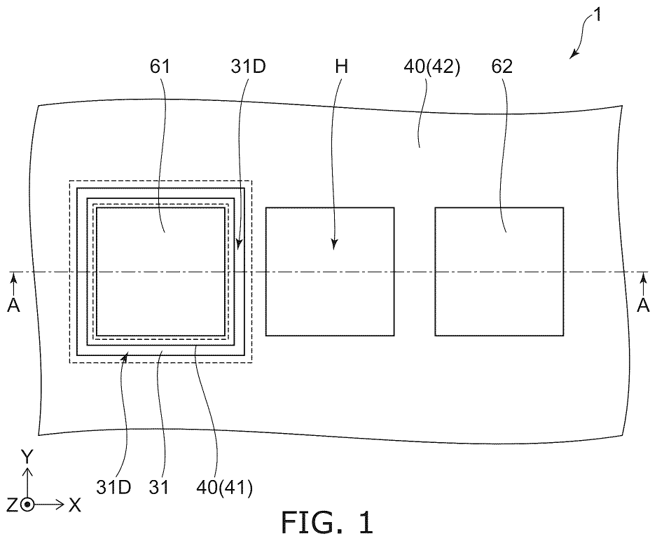

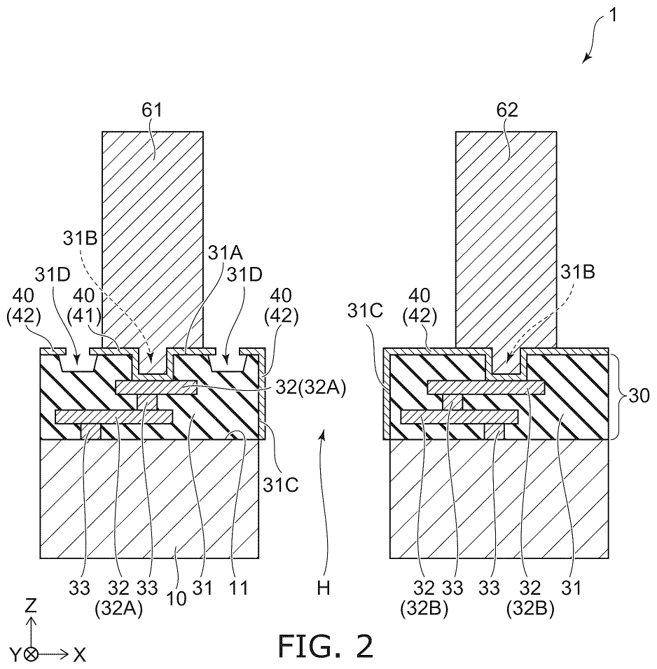

FIG. 1 is a schematic plan view of an electronic device 1 according to a first embodiment. FIG. 2 is a cross-sectional view taken along line A-A in FIG. 1.

The electronic device 1 according to the first embodiment includes a substrate 10, a wiring portion 30, a conductive film 40, and a through hole H extending through the wiring portion 30 and the substrate 10 in a first direction Z. Two directions orthogonal to each other in a plane orthogonal to the first direction Z are defined as a second direction X and a third direction Y.

The substrate 10 includes a first face 11. The substrate 10 is, for example, a silicon substrate. For example, a control element, such as a semiconductor transistor, is formed on the first face 11 side of the substrate 10.

The wiring portion 30 is provided on the first face 11 of the substrate 10. The wiring portion 30 includes a wiring layer 32 in at least one layer. This embodiment illustrates an example in which the wiring portion 30 has a multilayer wiring structure including wiring layers 32 in multiple layers. The wiring portion 30 includes the wiring layer 32 and an insulating layer 31. The wiring layer 32 is provided in the insulating layer 31. In a case where wiring layers 32 in multiple layers are provided, the wiring portion 30 further includes a conductive via 33 connecting the wiring layers 32 in different layers to each other. The wiring layer 32 is electrically connected to the control element, such as a semiconductor transistor, formed on the substrate 10. For example, the semiconductor transistor is formed at a position apart from the through hole H and is connected to the wiring layer 32.

The insulating layer 31 includes a face that is in contact with the first face 11 of the substrate 10, and a surface 31A located on the side opposite to the first face 11 of the substrate 10 (the side opposite to the face that is in contact with the first face 11). The insulating layer 31 includes an opening portion 31B reaching the wiring layer 32 from the surface 31A. As the material of the insulating layer 31, for example, silicon oxide or silicon nitride can be used.

The conductive film 40 is provided on the surface 31A of the insulating layer 31. The conductive film 40 is also provided in the opening portion 31B and is connected to the wiring layer 32 in the opening portion 31B. The conductive film 40 provided on the surface 31A and the conductive film 40 provided in the opening portion 31B are continuous. The conductive film 40 is also provided on an inner side surface 31C of the insulating layer 31 in the through hole H. As the material of the conductive film 40, for example, TiN (titanium nitride) can be used.

The insulating layer 31 includes a recessed portion 31D recessed from the surface 31A toward the substrate 10 in the first direction Z and exposed from the conductive film 40. The recessed portion 31D includes an inner wall that is continuous to the surface 31A of the insulating layer 31 and a bottom surface that is located closer to the substrate 10 than the surface 31A. The conductive film 40 is not provided on the inner wall and the bottom surface of the recessed portion 31D.

The electronic device 1 according to the first embodiment further includes a first electrode 61 and a second electrode 62 provided on the conductive film 40 and electrically connected to the conductive film 40. Each of the first electrode 61 and the second electrode 62 extends from the conductive film 40 toward the side opposite to the substrate 10 in the first direction Z. For example, the first electrode 61 and the second electrode 62 are apart from each other with the through hole H interposed therebetween in the second direction X. As the material of the first electrode 61 and the second electrode 62, for example, Au (gold) can be used.

The conductive film 40 is patterned to correspond to the first electrode 61 and the second electrode 62, and is separated into a first film 41 and a second film 42. The first film 41 is connected to the first electrode 61, and the second film 42 is connected to the second electrode 62. The first film 41 and the second film 42 are separated from each other above the recessed portion 31D.

As shown in FIG. 1, the second film 42 surrounds the first film 41 in plan view. In plan view, the recessed portion 31D is located at least between the first electrode 61 and the through hole H. In the example in FIG. 1, the recessed portion 31D continuously surrounds the first film 41 of the conductive film 40 and the first electrode 61 in plan view. In plan view, the outer edge of the first electrode 61 is located inside the outer edge of the first film 41.

As shown in FIG. 2, a part of the first electrode 61 is connected to the first film 41 in the opening portion 31B. A part of the second electrode 62 is connected to the second film 42 in the opening portion 31B. The wiring layer 32 includes a first wiring portion 32A and a second wiring portion 32B connected to different electric systems. The first electrode 61 is electrically connected to the first wiring portion 32A via the first film 41. The second electrode 62 is electrically connected to the second wiring portion 32B via the second film 42.

A first system in which the first wiring portion 32A and the first electrode 61 are electrically connected via the first film 41 and a second system in which the second wiring portion 32B and the second electrode 62 are electrically connected via the second film 42 can be controlled independently of each other. To the first electrode 61 and the second electrode 62, different potentials can be applied. For example, when a positive potential is applied to the first system and a ground potential is applied to the second system, an electric field can be generated in the through hole H. The electric field generated in the through hole H can deflect a charged particle beam, such as an electron beam, passing through the through hole H.

The conductive film 40 can suppress charging of the surface 31A of the insulating layer 31 and the inner side surface 31C of the insulating layer 31 in the through hole H, and can suppress abnormal deflection of the charged particle beam. A region that separates the first film 41 and the second film 42 from each other on the surface 31A side of the insulating layer 31 is exposed from the conductive film 40 and can be charged. According to this embodiment, the recessed portion 31D is provided in the insulating layer 31 in the region separating the first film 41 and the second film 42. Since the recessed portion 31D is provided, the exposed portion of the insulating layer 31 can be located farther from the through hole H than in a case where the recessed portion 31D is not provided. Accordingly, a leaking electric field leaking into the through hole H due to charging of the exposed portion (the recessed portion 31D) of the insulating layer 31 can be reduced, and variation in control of the charged particle beam can be reduced.

According to this embodiment, a part of the conductive film 40 protrudes from the surface 31A of the insulating layer 31 to a position so as to cover a part of the opening of the recessed portion 31D. The part of the conductive film 40 covers a part of the opening of the recessed portion 31D like an eave. Accordingly, the leaking electric field from the charged recessed portion 31D can be easily released to the conductive film 40, and the effect of the leaking electric field on the inside of the through hole H can be further reduced.

The electronic device 1 according to the first embodiment can include, for example, a plurality of through holes H, a plurality of first electrodes 61, and a plurality of second electrodes 62. For one through hole H, a pair of the first electrode 61 and the second electrode 62 is disposed.

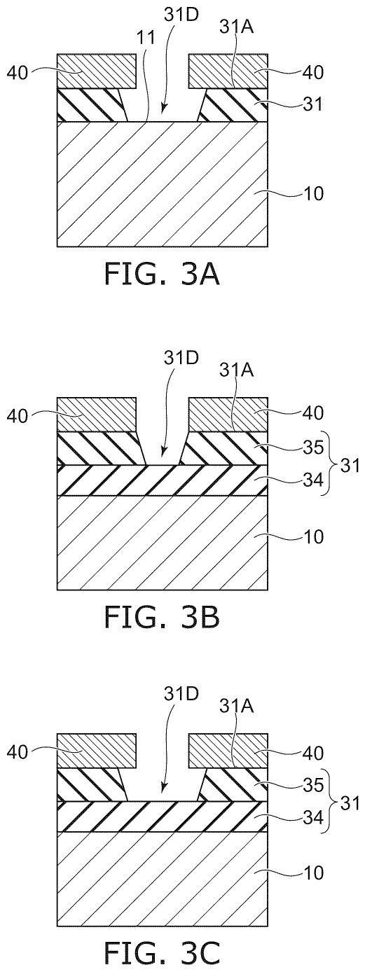

As shown in FIG. 3A, the first face 11 of the substrate 10 may be exposed in the bottom of the recessed portion 31D of the insulating layer 31. The substrate 10 is, for example, a conductive silicon substrate, and when the substrate 10 is exposed in the bottom of the recessed portion 31D, the exposed area of the insulating layer 31 in the recessed portion 31D can be reduced. Accordingly, the amount of charging in the recessed portion 31D can be reduced, and the leaking electric field leaking into the through hole H can be reduced.

As shown in FIG. 3B, the insulating layer 31 may include a first layer 34, and a second layer 35 provided on the first layer 34 and including the recessed portion 31D. The recessed portion 31D can be formed by patterning (separating) the conductive film 40, and subsequently etching the insulating layer 31 exposed from the conductive film 40. The material of the first layer 34 and the material of the second layer 35 are different, and the first layer 34 functions as an etching stopper upon forming of the recessed portion 31D in the second layer 35 by etching. For example, the first layer 34 can be a silicon nitride layer and the second layer 35 can be a silicon oxide layer.

In the example shown in FIG. 3B, the conductive film 40 does not protrude from the surface 31A of the insulating layer 31 toward the opening of the recessed portion 31D. The recessed portion 31D as described above can be formed by, for example, etching the second layer 35 by a Reactive Ion Etching (RIE) method using a fluorine-containing gas.

For example, the recessed portion 31D shown in FIG. 3C can be formed by etching the second layer 35 in an isotropic manner using fluorine vapor.

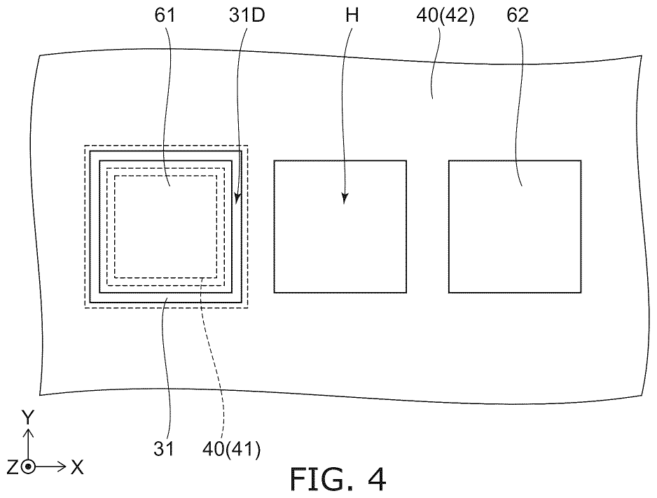

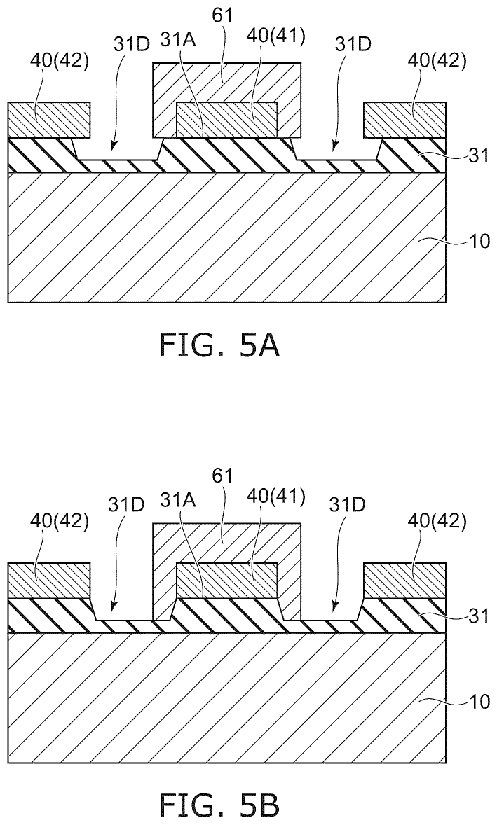

As shown in FIG. 4, in plan view, the outer edge (depicted in a dashed line) of the first film 41 of the conductive film 40 may be located inside the outer edge of the first electrode 61. In this case, as shown in FIGS. 5A and 5B, the first electrode 61 covers the upper surface and the side surface of the first film 41, and the strength of connection between the first electrode 61 and the first film 41 can be increased.

In the example shown in FIG. 5A, a part of the first electrode 61 protrudes from the surface 31A of the insulating layer 31 to a position so as to cover a part of the opening of the recessed portion 31D. The recessed portion 31D shown in FIG. 5A can be formed by forming the first electrode 61 covering the first film 41, and subsequently, for example, etching the insulating layer 31 in an isotropic manner using fluorine vapor.

In the example shown in FIG. 5B, a part of the first electrode 61 is located in the recessed portion 31D. In this example, the recessed portion 31D is formed, and subsequently, the first electrode 61 covering the first film 41 is formed.

### Second Embodiment

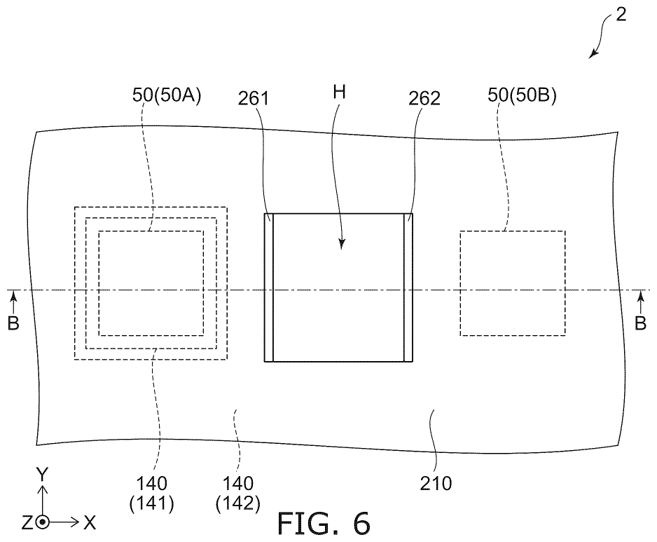

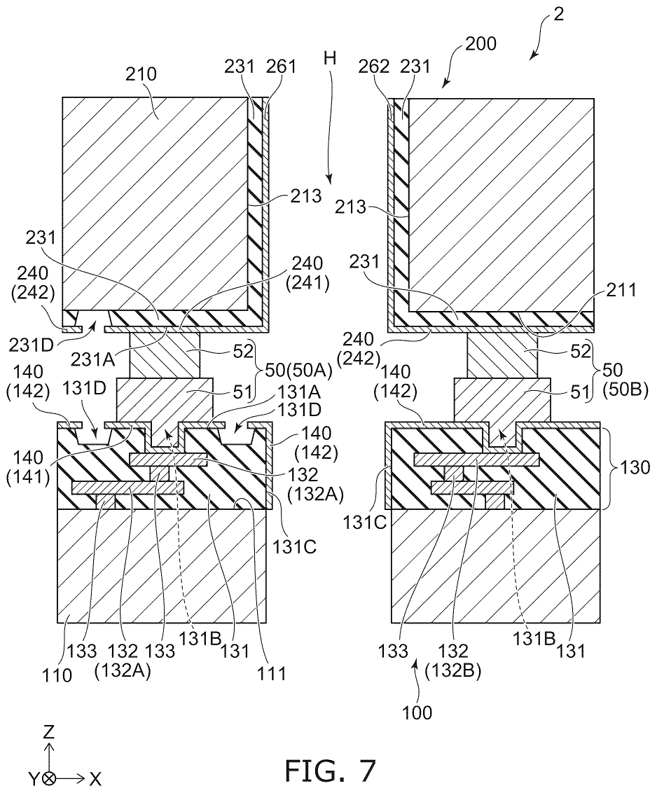

FIG. 6 is a schematic plan view of an electronic device 2 according to a second embodiment. FIG. 7 is a cross-sectional view taken along line B-B in FIG. 6.

The electronic device 2 according to the second embodiment includes a first chip 100, a second chip 200 facing the first chip 100 in the first direction Z, a plurality of bonding members 50, and a through hole H extending through the first chip 100 and the second chip 200 in the first direction Z. The plurality of bonding members 50 are provided between the first chip 100 and the second chip 200 in the first direction Z, and bond the first chip 100 and the second chip 200 together.

The first chip 100 includes a first substrate 110, a wiring portion 130, and a first conductive film 140.

The first substrate 110 includes a first face 111 facing the second chip 200 in the first direction Z. The first substrate 110 is, for example, a silicon substrate. For example, a control element, such as a semiconductor transistor, is formed on the first face 111 side of the first substrate 110. For example, the semiconductor transistor is formed at a position apart from the through hole H and is connected to a wiring layer 132.

The wiring portion 130 is provided on the first face 111 of the first substrate 110. The wiring portion 130 includes the wiring layer 132 in at least one layer. This embodiment illustrates an example in which the wiring portion 130 has a multilayer wiring structure including wiring layers 132 in multiple layers. The wiring portion 130 includes the wiring layer 132 and a first insulating layer 131. The wiring layer 132 is provided in the first insulating layer 131. In a case where wiring layers 132 in multiple layers are provided, the wiring portion 130 further includes a conductive via 133 connecting the wiring layers 132 in different layers to each other. The wiring layer 132 is electrically connected to the control element, such as a semiconductor transistor, formed on the first substrate 110. The wiring layer 132 includes a first wiring portion 132A and a second wiring portion 132B connected to different electric systems.

The first insulating layer 131 includes a face that is in contact with the first face 111 of the first substrate 110, and a first surface 131A located on the side opposite to the first face 111 of the first substrate 110 (the side opposite to the face that is in contact with the first face 111). The first insulating layer 131 includes an opening portion 131B reaching the wiring layer 132 from the first surface 131A. As the material of the first insulating layer 131, for example, silicon oxide or silicon nitride can be used.

The first conductive film 140 is provided on the first surface 131A of the first insulating layer 131. The first conductive film 140 is also provided in the opening portion 131B and is connected to the wiring layer 132 in the opening portion 131B. The first conductive film 140 provided on the first surface 131A and the first conductive film 140 provided in the opening portion 131B are continuous. The first conductive film 140 is also provided on an inner side surface 131C of the first insulating layer 131 in the through hole H. As the material of the first conductive film 140, for example, TiN can be used.

The first insulating layer 131 includes a first recessed portion 131D recessed from the first surface 131A toward the first substrate 110 in the first direction Z and exposed from the first conductive film 140. The first recessed portion 131D includes an inner wall that is continuous to the first surface 131A of the first insulating layer 131 and a bottom surface that is located closer to the first substrate 110 than the first surface 131A. The first conductive film 140 is not provided on the inner wall and the bottom surface of the first recessed portion 131D.

The second chip 200 includes a second substrate 210, a second conductive film 240, and a second insulating layer 231.

The second substrate 210 includes a second face 211 facing the first face 111 of the first substrate 110 in the first direction Z. The second substrate 210 is, for example, a silicon substrate.

The second conductive film 240 is provided on the second face 211 of the second substrate 210 with the second insulating layer 231 interposed therebetween. The second conductive film 240 is provided on a second surface 231A of the second insulating layer 231 located on the side opposite to the second face 211 of the second substrate 210. The second insulating layer 231 is provided between the second face 211 of the second substrate 210 and the second conductive film 240. As the material of the second conductive film 240, for example, TiN can be used. As the material of the second insulating layer 231, for example, silicon oxide or silicon nitride can be used.

The second insulating layer 231 includes a second recessed portion 231D recessed from the second surface 231A toward the second substrate 210 in the first direction Z and exposed from the second conductive film 240. The second recessed portion 231D includes an inner wall that is continuous to the second surface 231A of the second insulating layer 231 and a bottom surface that is located closer to the second substrate 210 than the second surface 231A. The second conductive film 240 is not provided on the inner wall and the bottom surface of the second recessed portion 231D. In this embodiment, the second substrate 210 is exposed in the bottom surface of the second recessed portion 231D. Alternatively, the second insulating layer 231 may be exposed in the bottom surface of the second recessed portion 231D.

The second chip 200 further includes a first electrode 261 and a second electrode 262 provided on an inner side surface 213 of the second substrate 210 in the through hole H. The second insulating layer 231 is provided between the inner side surface 213 of the second substrate 210 and the first electrode 261, and between the inner side surface 213 of the second substrate 210 and the second electrode 262. The first electrode 261 and the second electrode 262 are provided on the inner side surface 213 of the second substrate 210 with the second insulating layer 231 provided on the inner side surface 213 of the second substrate 210 interposed. The first electrode 261 and the second electrode 262 are separated from each other on the inner side surface 213 of the second substrate 210, and face each other across the through hole H. The first electrode 261 and the second electrode 262 are connected to the second conductive film 240. The first electrode 261 and the second electrode 262 are, for example, a single-layer metal film or a multilayer metal film including TiN, W (tungsten), etc.

The second conductive film 240 is patterned to correspond to the first electrode 261 and the second electrode 262, and is separated into a third film 241 and a fourth film 242. The third film 241 is connected to the first electrode 261, and the fourth film 242 is connected to the second electrode 262. The third film 241 and the fourth film 242 are separated at a position facing the second recessed portion 231D.

The first conductive film 140 of the first chip 100 is also patterned and is separated into a first film 141 and a second film 142. The plurality of bonding members 50 are provided between the first conductive film 140 and the second conductive film 240, and bond the first substrate 110 and the second substrate 210 together in the first direction Z. The bonding members 50 are conductive. The plurality of bonding members 50 include a first bonding member 50A and a second bonding member 50B connected to different electric systems. The first film 141 is connected to the third film 241 via the first bonding member 50A, and the second film 142 is connected to the fourth film 242 via the second bonding member 50B. The first film 141 and the second film 142 are separated at a position facing the first recessed portion 131D.

The bonding member 50 is formed by bonding a first metal portion 51 provided on the first chip 100 side and a second metal portion 52 provided on the second chip 200 side. The first metal portion 51 and the second metal portion 52 include, for example, Au (gold), and the bonding member 50 is an Au-to-Au bonded body. The boundary between the first metal portion 51 and the second metal portion 52 might not be clearly visible.

The first metal portion 51 is connected to the first conductive film 140 on the first surface 131A of the first insulating layer 131. A part of the first metal portion 51 is connected to the first conductive film 140 in the opening portion 131B of the first insulating layer 131.

The first electrode 261 is electrically connected to the first wiring portion 132A via the third film 241 of the second conductive film 240, the first bonding member 50A, and the first film 141 of the first conductive film 140. The second electrode 262 is electrically connected to the second wiring portion 132B via the fourth film 242 of the second conductive film 240, the second bonding member 50B, and the second film 142 of the first conductive film 140.

A first system in which the first wiring portion 132A and the first electrode 261 are electrically connected and a second system in which the second wiring portion 132B and the second electrode 262 are electrically connected can be controlled independently of each other. To the first electrode 261 and the second electrode 262, different potentials can be applied. For example, when a positive potential is applied to the first system and a ground potential is applied to the second system, an electric field can be generated in the through hole H. The electric field generated in the through hole H can deflect a charged particle beam, such as an electron beam, passing through the through hole H.

The first conductive film 140 can suppress charging of the first surface 131A of the first insulating layer 131 and the inner side surface 131C of the first insulating layer 131 in the through hole H, and can suppress abnormal deflection of the charged particle beam. According to this embodiment, the first recessed portion 131D is provided in the first insulating layer 131 in a region separating the first film 141 and the second film 142 of the first conductive film 140. Since the first recessed portion 131D is provided, the exposed portion of the first insulating layer 131 can be located farther from the through hole H than in a case where the first recessed portion 131D is not provided. Accordingly, a leaking electric field leaking into the through hole H due to charging of the exposed portion (the first recessed portion 131D) of the first insulating layer 131 can be reduced, and variation in control of the charged particle beam can be reduced.

Also in the second embodiment, a part of the conductive film protrudes from the surface of the insulating layer to a position so as to cover a part of the opening of the recessed portion, as in the first embodiment. According to this embodiment, a part of the first conductive film 140 protrudes from the first surface 131A of the first insulating layer 131 to a position so as to cover a part of the opening of the first recessed portion 131D. The part of the first conductive film 140 covers a part of the opening of the first recessed portion 131D like an eave. Accordingly, the leaking electric field from the charged first recessed portion 131D can be easily released to the first conductive film 140, and the effect of the leaking electric field on the inside of the through hole H can be further reduced.

The second conductive film 240 can suppress charging of the second surface 231A of the second insulating layer 231, and can suppress abnormal deflection of the charged particle beam. The second recessed portion 231D is provided in the second insulating layer 231 in a region separating the third film 241 and the fourth film 242 of the second conductive film 240. Accordingly, a leaking electric field leaking into the through hole H due to charging of the exposed portion (the second recessed portion 231D) of the second insulating layer 231 can be reduced, and variation in control of the charged particle beam can be reduced.

A part of the second conductive film 240 protrudes from the second surface 231A of the second insulating layer 231 to a position so as to cover a part of the opening of the second recessed portion 231D. Accordingly, the leaking electric field from the charged second recessed portion 231D can be easily released to the second conductive film 240, and the effect of the leaking electric field on the inside of the through hole H can be further reduced.

The electronic device 2 according to the second embodiment can include, for example, a plurality of through holes H. In each through hole H, a pair of the first electrode 261 and the second electrode 262 is disposed.

The modifications shown in FIGS. 3A to 3C are also applicable to the electronic device 2 according to the second embodiment shown in FIG. 6 and FIG. 7.

The electronic devices 1 and 2 described above can be used in, for example, an electron microscope for observing surfaces with an electron beam, an electron beam writer for writing fine patterns on masks or wafers, or an inspection apparatus for detecting defects by scanning a surface with an electron beam.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic device comprising:
a substrate;
an insulating layer provided on the substrate and including a surface located on a side opposite to the substrate;
a through hole extending through the insulating layer and the substrate in a first direction; and
a conductive film provided on the surface of the insulating layer and on an inner side surface of the insulating layer in the through hole,
the insulating layer including a recessed portion recessed toward the substrate from the surface and exposed from the conductive film.

2. The electronic device according to claim 1, wherein a part of the conductive film protrudes from the surface to a position so as to cover a part of an opening of the recessed portion.

3. The electronic device according to claim 2, further comprising: an electrode provided on the conductive film.

4. The electronic device according to claim 1, further comprising: an electrode provided on the conductive film.

5. The electronic device according to claim 4, wherein a part of the electrode protrudes from the surface to a position so as to cover a part of an opening of the recessed portion.

6. The electronic device according to claim 4, wherein a part of the electrode is located in the recessed portion.

7. The electronic device according to claim 3, further comprising: a wiring layer provided in the insulating layer and electrically connected to the electrode via the conductive film.

8. The electronic device according to claim 3, wherein the recessed portion is located between the electrode and the through hole in plan view.

9. The electronic device according to claim 1, wherein the substrate is exposed in a bottom of the recessed portion.

10. The electronic device according to claim 1, wherein
the insulating layer includes a first layer, and a second layer provided on the first layer and including the recessed portion, and
a material of the first layer and a material of the second layer are different.

11. An electronic device comprising:
a first substrate;
a second substrate facing the first substrate in a first direction;
a first insulating layer provided on a first face of the first substrate facing the second substrate, and including a first surface located on a side opposite to the first face;
a through hole extending through the second substrate, the first insulating layer, and the first substrate in the first direction;
a first conductive film provided on the first surface of the first insulating layer and on an inner side surface of the first insulating layer in the through hole;
a second conductive film provided on a second face of the second substrate facing the first substrate; and
a bonding member provided between the first conductive film and the second conductive film and bonding the first substrate and the second substrate together in the first direction,
the first insulating layer including a first recessed portion recessed toward the first substrate from the first surface and exposed from the first conductive film.

12. The electronic device according to claim 11, further comprising:
a second insulating layer provided between the second face of the second substrate and the second conductive film,
the second conductive film being provided on a second surface of the second insulating layer located on a side opposite to the second face of the second substrate,
the second insulating layer including a second recessed portion recessed toward the second substrate from the second surface and exposed from the second conductive film.

13. The electronic device according to claim 11, further comprising: a wiring layer provided in the first insulating layer and electrically connected to the second conductive film via the first conductive film and the bonding member.

14. The electronic device according to claim 13, further comprising: an electrode provided on an inner side surface of the second substrate in the through hole and electrically connected to the wiring layer via the second conductive film, the bonding member, and the first conductive film.
